(19) United States
(12) Patent Application Publication
(10) Pub. No.: US 2024/0321790 A1
(43) Pub. Date: Sep. 26, 2024

(54) BONDING-TYPE INTERCONNECTION MEMBER

(71) Applicants: Kabushiki Kaisha Toshiba, Tokyo (JP); Toshiba Electronic Devices & Storage Corporation, Tokyo (JP)

(72) Inventors: Kei OBARA, Kawasaki Kanagawa (JP); Kazumichi TSUMURA, Shinagawa Tokyo (JP)

(21) Appl. No.: 18/458,118

(22) Filed: Aug. 29, 2023

(30) Foreign Application Priority Data
Mar. 22, 2023 (JP) 2023-045812

(51) Int. Cl. H01L 23/00; H01L 25/065

(52) U.S. Cl. CPC H01L 24/05; H01L 24/13; H01L 25/0657; H01L 2224/0236; H01L 2224/0401; H01L 2224/05016; H01L 2224/05022; H01L 2224/05025; H01L 2224/05027; H01L 2224/05083; H01L 2224/05093; H01L 2224/05166; H01L 2224/05551; H01L 2224/05573; H01L 2224/05664; H01L 2224/05666; H01L 2224/13006; H01L 2224/13026; H01L 2224/13144; H01L 2225/06513

(57) ABSTRACT

A bonding-type interconnection member includes a first substrate having a first through hole extending in a first direction; a second substrate having a second through hole extending in the first direction; an interconnection portion stacked on at least one of the first substrate and the second substrate, and having a through hole continuous with the first through hole and the second through hole; a conductive film provided on a side surface of the through hole of the interconnection portion; at least two bonding metal portions positioned between the first substrate and the second substrate, and bonding the first substrate and the second substrate; and a foundation metal film provided between the bonding metal portions and the interconnection portion. The conductive film is made of a material different from a material of the bonding metal portions and a material of the foundation metal film.

### CROSS-REFERENCE TO RELATED APPLICATION

This application is based upon and claims the benefit of priority from Japanese Patent Application No. 2023-045812, filed on Mar. 22, 2023; the entire contents of which are incorporated herein by reference.

### FIELD

Embodiments described herein relate generally to a bonding-type interconnection member.

### BACKGROUND

A configuration in which a through hole is formed in an interconnection member is known.

### BRIEF DESCRIPTION OF THE DRAWINGS

FIG. 1 is a schematic plan view of a bonding-type interconnection member according to a first embodiment;

FIG. 2 is a cross-sectional view taken along a line A-A in FIG. 1;

FIG. 3A to FIG. 7 are schematic cross-sectional views showing a method for manufacturing the bonding-type interconnection member according to the first embodiment; and

FIG. 8 is a schematic cross-sectional view of a bonding-type interconnection member according to a second embodiment.

### DETAILED DESCRIPTION

According to one embodiment, a bonding-type interconnection member includes a first substrate having a first through hole extending in a first direction; a second substrate facing the first substrate in the first direction and having a second through hole extending in the first direction; an interconnection portion positioned between the first substrate and the second substrate in the first direction, stacked on at least one of the first substrate and the second substrate, and having a through hole continuous with the first through hole and the second through hole; a conductive film provided on a side surface of the through hole of the interconnection portion; at least two bonding metal portions positioned between the first substrate and the second substrate in the first direction, and bonding the first substrate and the second substrate; and a foundation metal film provided between the bonding metal portions and the interconnection portion, the conductive film being made of a material different from a material of the bonding metal portions and a material of the foundation metal film.

Hereinafter, embodiments will be described with reference to the drawings.

The drawings are schematic or conceptual. A relationship between a thickness and a width of each portion, a ratio of sizes between portions, and the like are not necessarily the same as the actual ones. Even if the same portions are shown, dimensions and ratios may be shown differently from each other in the drawings.

Same components are denoted by same reference numerals.

### First Embodiment

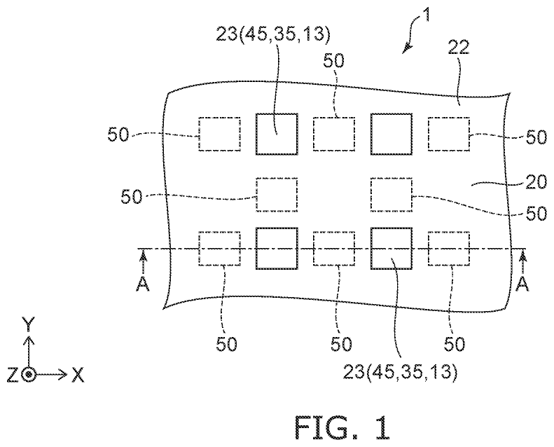

FIG. 1 is a schematic plan view of a bonding-type interconnection member 1 according to a first embodiment.

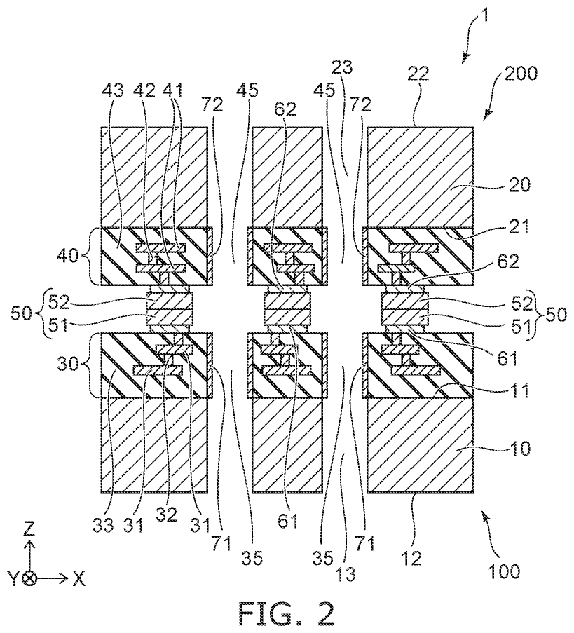

FIG. 2 is a cross-sectional view taken along a line A-A in FIG. 1.

The bonding-type interconnection member 1 includes a first chip 100 and a second chip 200. The first chip 100 and the second chip 200 are bonded via bonding metal portions 50, and are stacked in a first direction Z. Two directions orthogonal to the first direction Z are referred to as a second direction X and a third direction Y. The second direction X and the third direction Y are orthogonal to each other.

The first chip 100 includes a first substrate 10. The first substrate 10 has a first face 11 and a second face 12 positioned on an opposite-side face from the first face 11 in the first direction Z. The first substrate 10 has first through holes 13 penetrating from the first face 11 to the second face 12 and extending in the first direction Z. The first substrate 10 is, for example, a silicon substrate.

The second chip 200 includes a second substrate 20. The second substrate 20 has a third face 21 facing the first face 11 of the first substrate 10 in the first direction Z, and a fourth face 22 positioned on an opposite-side face from the third face 21 in the first direction Z. The second substrate 20 has second through holes 23 penetrating from the third face 21 to the fourth face 22 and extending in the first direction Z. The second substrate 20 is, for example, a silicon substrate.

The first chip 100 includes a first interconnection portion 30 stacked on the first substrate 10. The first interconnection portion 30 is provided on the first face 11 of the first substrate 10. In the first direction Z, the first interconnection portion 30 is positioned between the first substrate 10 and the second substrate 20. The first interconnection portion 30 includes a first insulating layer 33 and first interconnection layers 31 provided in the first insulating layer 33. The first interconnection portion 30 includes, for example, the multiple first interconnection layers 31 and first conductive vias 32 connecting the first interconnection layers 31 of different layers. The first interconnection portion 30 has first interconnection portion through holes 35 continuous with the first through holes 13 and the second through holes 23 in the first direction Z.

The second 200 includes chip a second interconnection portion 40 stacked on the second substrate 20. The second interconnection portion 40 is provided on the third face 21 of the second substrate 20. In the first direction Z, the second interconnection portion 40 is positioned between the first interconnection portion 30 and the second substrate 20. The second interconnection portion 40 includes a second insulating layer 43 and second interconnection layers 41 provided in the second insulating layer 43. The second interconnection portion 40 includes, for example, the multiple second interconnection layers 41 and second conductive vias 42 connecting the second interconnection layers 41 of different layers. The second interconnection portion 40 has second interconnection portion through holes 45 continuous with the first through holes 13, the first interconnection portion through holes 35, and the second through holes 23 in the first direction Z.

As shown in FIG. 1, for example, the multiple second through holes 23 are arranged in the second direction X and the third direction Y. The second interconnection portion through hole 45 is positioned below the second through hole 23, the first interconnection portion through hole 35 is positioned below the second interconnection portion through hole 45, and the first through hole 13 is positioned below the first interconnection portion through hole 35.

The bonding metal portion 50 is positioned between the first interconnection portion 30 and the second interconnection portion 40 in the first direction Z. The multiple bonding metal portions 50 are disposed between the first chip 100 and the second chip 200. As shown in FIG. 1, in a plan view, one bonding metal portion 50 is disposed between the second through holes 23 adjacent in at least one of the second direction X and the third direction Y. Conversely, in a plan view, one second through hole 23 is disposed between the bonding metal portions 50 adjacent in at least one of the second direction X and the third direction Y.

As will be described later, one bonding metal portion 50 is formed by integrating a first bonding metal portion 51 provided on a first chip 100 side and a second bonding metal portion 52 provided on a second chip 200 side by metal diffusion bonding by applying heat and a force.

The first chip 100 further includes a first foundation metal film 61 provided between the bonding metal portion 50 and the first interconnection portion 30. The first foundation metal film 61 increases an adhesion force between the bonding metal portion 50 and the first interconnection portion 30.

The second chip 200 further includes a second foundation metal film 62 provided between the bonding metal portion 50 and the second interconnection portion 40. The second foundation metal film 62 increases an adhesion force between the bonding metal portion 50 and the second interconnection portion 40.

The first chip 100 further includes a first conductive film 71 provided on side surfaces of the first interconnection portion through holes 35. The first conductive film 71 covers an entire side surface of the first interconnection portion through hole 35.

The second chip 200 further includes a second conductive film 72 provided on side surfaces of the second interconnection portion through holes 45. The second conductive film 72 covers an entire side surface of the second interconnection portion through hole 45.

For example, a charged particle beam passes through the second through hole 23, the second interconnection portion through hole 45, the first interconnection portion through hole 35, and the first through hole 13. By bonding the two chips (the first chip 100 and the second chip 200) each having through holes, the bonding-type interconnection member 1 having deep through holes, which is difficult to form with a single chip, can be implemented.

The bonding metal portion 50 can function not only to bond the first chip 100 and the second chip 200, but also as a conductive portion to electrically connect the first chip 100 and the second chip 200. In this case, the first interconnection layers 31 of the first interconnection portion 30 of the first chip 100 are electrically connected to the bonding metal portions 50 via the first conductive vias 32 and the first foundation metal film 61. The second interconnection layers 41 of the second interconnection portion 40 of the second chip 200 are electrically connected to the bonding metal portions 50 via the second conductive vias 42 and the second foundation metal film 62.

According to the embodiment, the side surfaces of the first interconnection portion through holes 35 formed in the first interconnection portion 30 are covered with the first conductive film 71, and the first insulating layer 33 of the first interconnection portion 30 is not exposed on the side surfaces of the first interconnection portion through holes 35. The side surfaces of the second interconnection portion through holes 45 formed in the second interconnection portion 40 are covered with the second conductive film 72, and the second insulating layer 43 of the second interconnection portion 40 is not exposed on the side surfaces of the second interconnection portion through holes 45. Accordingly, under a usage environment, during preparation for usage, or during storage of the bonding-type interconnection member 1, moisture absorption to the side surface of the first insulating layer 33 and the side surface of the second insulating layer 43 can be prevented, and oxidation of the first interconnection layers 31 and the second interconnection layers 41 can be prevented. As a result, reliability of the bonding-type interconnection member 1 can be enhanced.

In addition, charging of the side surface of the first insulating layer 33 and the side surface of the second insulating layer 43 can be prevented by the first conductive film 71 and the second conductive film 72, and abnormal deflection of the charged particle beam can be prevented. As a result, reliability of the bonding-type interconnection member 1 can be enhanced.

In the embodiment, the first conductive film 71 and the second conductive film 72 are made of a material different from a material of the bonding metal portions 50 and a material of the first foundation metal film 61 and the second foundation metal film 62. Here, the material refers to a material that mainly constitutes each member. For example, the bonding metal portion 50 mainly contains gold, the first foundation metal film 61 and the second foundation metal film 62 mainly include palladium, titanium, or a stacked film of a palladium film and a titanium film, and the first conductive film 71 and the second conductive film 72 mainly contain titanium nitride. Accordingly, as will be described later, damage and disappearance of the first conductive film 71 and the second conductive film 72 due to etching when the first foundation metal film 61 and the second foundation metal film 62 are patterned can be prevented.

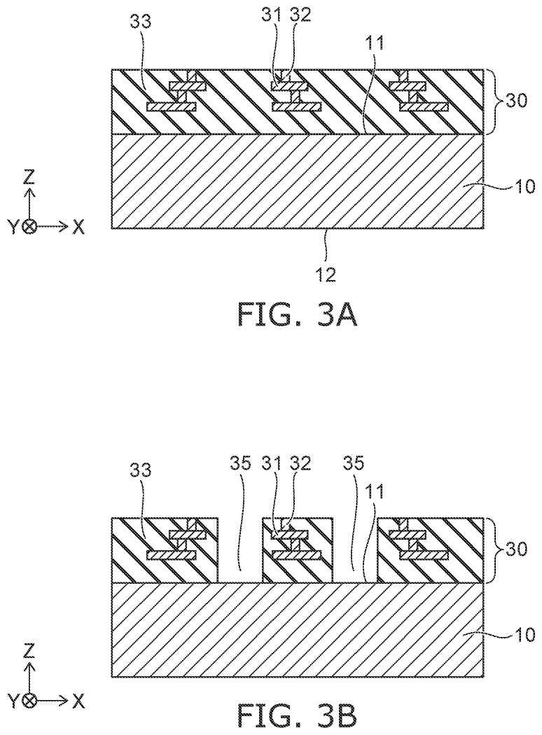

Next, a manufacturing method of the bonding-type interconnection member 1 according to the first embodiment will be described with reference to FIGS. 3A to 7.

As shown in FIG. 3A, the first interconnection portion 30 is formed on the first face 11 of the first substrate 10. As described above, the first interconnection portion 30 has, for example, a multilayer interconnection structure.

As shown in FIG. 3B, the first interconnection portion through holes 35 are formed in the first interconnection portion 30. The first interconnection portion through holes 35 penetrate the first interconnection portion 30 and reach the first face 11 of the first substrate 10.

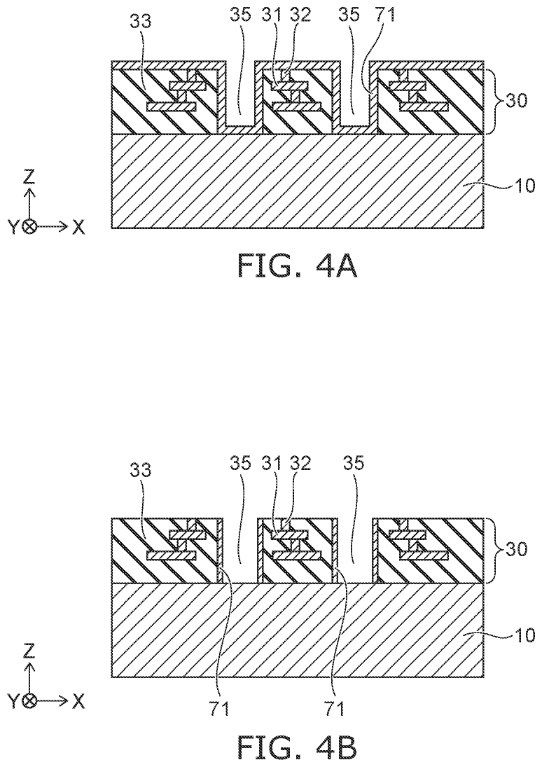

After the first interconnection portion through holes 35 are formed, the first conductive film 71 is formed as shown in FIG. 4A. As the first conductive film 71, for example, a titanium nitride film mainly containing titanium nitride is formed by a sputtering method. The first conductive film 71 is continuously formed on an upper surface of the first interconnection portion 30, and side surfaces and bottom surfaces of the first interconnection portion through holes 35.

After the first conductive film 71 is formed, the first conductive film 71 is etched back by, for example, a reactive ion etching (RIE) method, and as shown in FIG. 4B, the first conductive film 71 is left on the side surfaces of the first interconnection portion through holes 35.

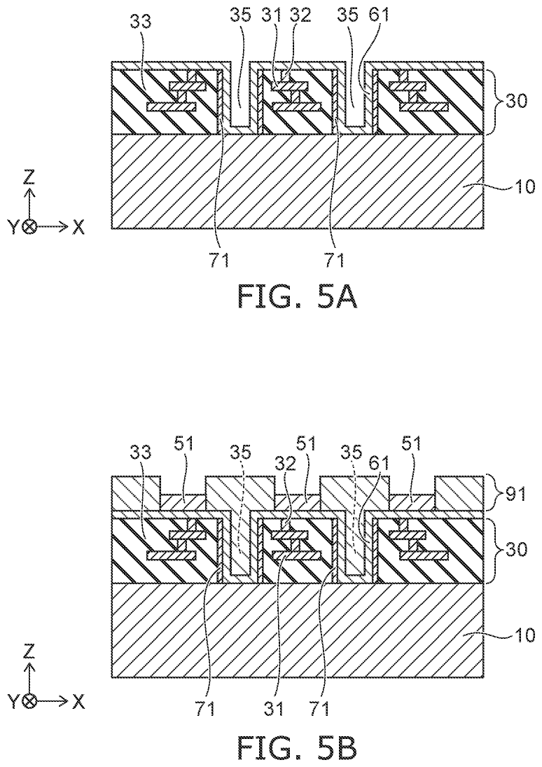

Thereafter, as shown in FIG. 5A, the first foundation metal film 61 is formed. As the first foundation metal film 61, for example, a metal film mainly including palladium, titanium, or a stacked film of a palladium film and a titanium film is formed by a sputtering method. The first foundation metal film 61 is continuously formed on the upper surface of the first interconnection portion 30, the first conductive film 71 formed on the side surfaces of the first interconnection portion through holes 35, and the bottom surfaces of the first interconnection portion through holes 35. At this time, the first foundation metal film 61 is electrically connected to the first conductive vias 32 of the first interconnection portion 30 on the upper surface of the first interconnection portion 30.

After the first foundation metal film 61 is formed, as shown in FIG. 5B, the first bonding metal portions 51 are formed as a metal film mainly containing gold by a plating method using resist masks 91. The first foundation metal film 61 functions as a seed layer for plating. The first bonding metal portions 51 are formed on the first foundation metal film 61 positioned on the upper surface of the first interconnection portion 30.

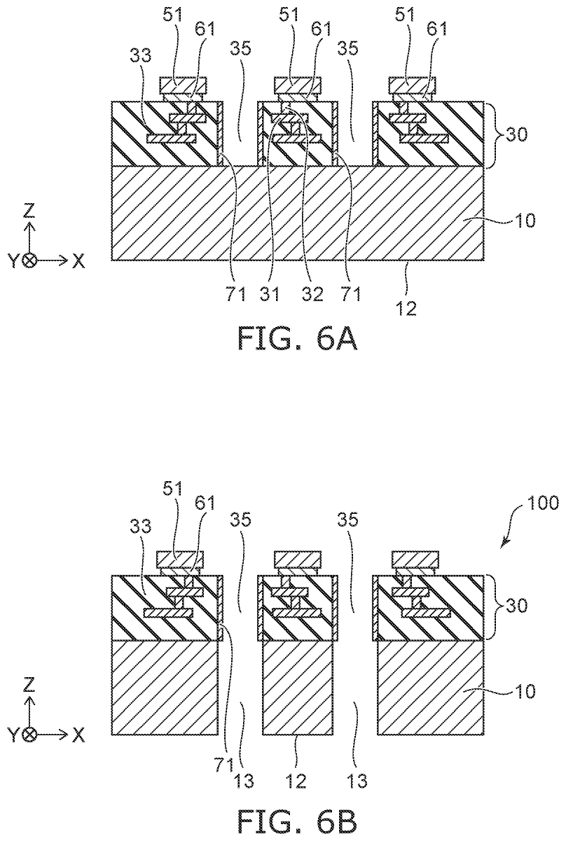

After the first bonding metal portions 51 are formed, the resist masks 91 are removed. Then, an exposed portion of the first foundation metal film 61 due to the removal of the resist masks 91 is removed by a wet etching method. Since the first bonding metal portion 51 is made of a material different from a material of the first foundation metal film 61, the first bonding metal portion 51 functions as a mask when removing the first foundation metal film 61 by the wet etching. As shown in FIG. 6A, the first foundation metal film 61 under the first bonding metal portion 51 is left, and other parts of the first foundation metal film 61 are removed. At this time, since the first conductive film 71 is made of a material different from the material of the first foundation metal film 61, the first conductive films 71 has resistance to the wet etching. Accordingly, the first conductive film 71 can be reliably left on the side surfaces of the first interconnection portion through holes 35.

The first bonding metal portion 51 may be patterned by selective etching. In this case, since the first conductive film 71 is also made of a material different from the material of the first bonding metal portion 51, the first conductive film 71 has resistance when the first bonding metal portion 51 is etched, and the first conductive film 71 can be reliably left on the side surfaces of the first interconnection portion through holes 35.

After the first bonding metal portions 51 are formed, as shown in FIG. 6B, the first through holes 13 are formed in the first substrate 10. For example, the first through holes 13 are formed by an RIE method from a second face 12 side of the first substrate 10 to be connected to the first interconnection portion through holes 35. In this way, the first chip 100 is obtained.

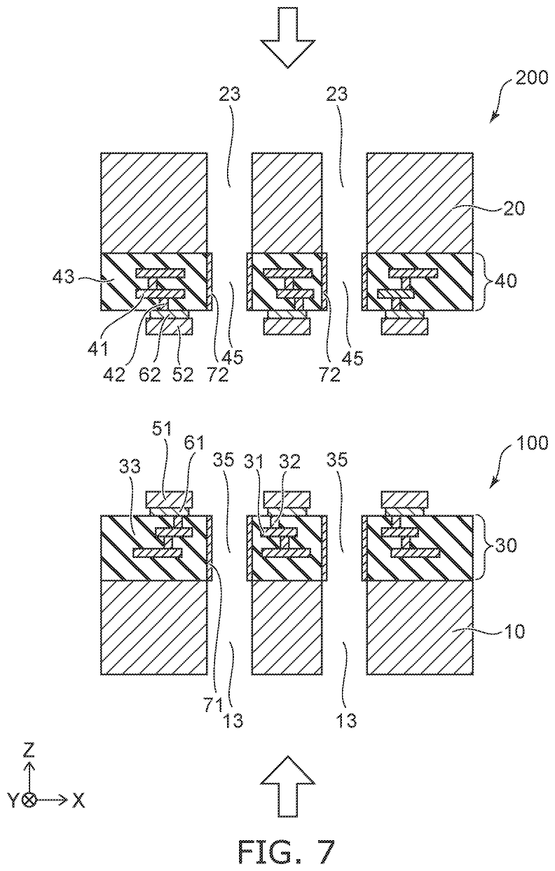

The second chip 200 can also be obtained by a process same as that of the first chip 100 described above. Then, as shown in FIG. 7, the first bonding metal portions 51 of the first chip 100 and the second bonding metal portions 52 of the second chip 200 face each other and are brought into contact with each other. Thereafter, heat and a force are applied to diffuse metals (in the example, gold) of the first bonding metal portions 51 and the second bonding metal portions 52, and the first bonding metal portions 51 and the second bonding metal portions 52 are bonded.

As a comparative example, it is conceivable to form the first conductive film 71 on the side surfaces of the first interconnection portion through holes 35 after patterning the first bonding metal portions 51. In this case, due to a metal residue when forming the first conductive film 71, there is concern that surfaces of the first bonding metal portions 51 may be unsuitable for bonding with the second bonding metal portions 52, or that the first bonding metal portions 51 to which different potentials are applied may be short-circuited.

According to the embodiment, before the first bonding metal portions 51 are formed, the first conductive film 71 is already formed on the side surfaces of the first interconnection portion through holes 35. Therefore, bonding between the first bonding metal portions 51 and the second bonding metal portions 52 can be satisfactorily performed, and short-circuiting between the first bonding metal portions 51 to which different potentials are applied can be prevented.

### Second Embodiment

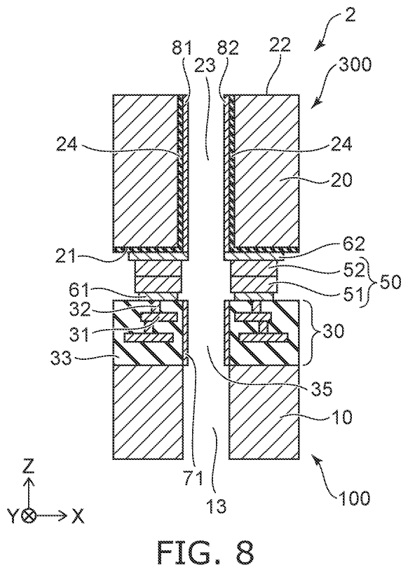

FIG. 8 is a schematic cross-sectional view of a bonding-type interconnection member 2 according to a second embodiment.

The first chip 100 and a second chip 300 are bonded via the bonding metal portions 50. The second chip 300 includes the second substrate 20. A interconnection portion is stacked only on the first substrate 10 of the first chip 100, and is not stacked on the second substrate 20 of the second chip 300. The second substrate 20 has the second through hole 23 continuous with the first interconnection portion through hole 35 and the first through hole 13. The bonding metal portions 50 are bonded to the third face 21 of the second substrate 20 via the second foundation metal film 62.

A first electrode film 81 and a second electrode film 82 are provided on side surfaces of the second through hole 23 of the second substrate 20. The first electrode film 81 and the second electrode film 82 are spaced apart from each other in the second direction X and are not connected in the second through hole 23.

Lower ends of the first electrode film 81 and the second electrode film 82 are connected to the second foundation metal film 62. The first electrode film 81 and the second electrode film 82 are electrically connected to the first interconnection layers 31 via the second foundation metal film 62, the bonding metal portions 50, the first foundation metal film 61, and the first conductive vias 32. The first interconnection layers 31 electrically connected to the first electrode film 81 and the first interconnection layers 31 electrically connected to the second electrode film 82 are not electrically connected, and different potentials can be applied to the first electrode film 81 and the second electrode film 82, respectively. Accordingly, a charged particle beam passing through the second through hole 23 can be deflected.

For example, when the second substrate 20 has conductivity such as a silicon substrate, insulating films 24 are provided between the first electrode film 81 and the second substrate 20 and between the second electrode film 82 and the second substrate 20. When the second substrate 20 is an insulating substrate, the first electrode film 81 and the second electrode film 82 may be directly formed on the second substrate 20.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A bonding-type interconnection member comprising:
a first substrate having a first through hole extending in a first direction;
a second substrate facing the first substrate in the first direction and having a second through hole extending in the first direction;
an interconnection portion positioned between the first substrate and the second substrate in the first direction, stacked on at least one of the first substrate and the second substrate, and having a through hole continuous with the first through hole and the second through hole;
a conductive film provided on a side surface of the through hole of the interconnection portion;
at least two bonding metal portions positioned between the first substrate and the second substrate in the first direction, and bonding the first substrate and the second substrate; and
a foundation metal film provided between the bonding metal portions and the interconnection portion,
the conductive film being made of a material different from a material of the bonding metal portions and a material of the foundation metal film.

2. The member according to claim 1, wherein
the conductive film covers an entire side surface of the through hole.

3. The member according to claim 1, wherein
the interconnection portion includes an interconnection layer electrically connected to the bonding metal portions via the foundation metal film.

4. The member according to claim 3, wherein
the interconnection portion includes an insulating layer,
the interconnection layer is provided in the insulating layer, and
the conductive film is provided on the side surface of the through hole in the insulating layer.

5. The member according to claim 4, wherein
the insulating layer is not exposed on the side surface of the through hole.

6. The member according to claim 1, wherein
the interconnection portion is stacked on each of the first substrate and the second substrate, and
the conductive film is provided on the side surface of the through hole of the interconnection portion stacked on each of the first substrate and the second substrate.

7. The member according to claim 1, further comprising:
an electrode film provided on a side surface of the second through hole, wherein
the interconnection portion is stacked on the first substrate, and
the interconnection portion including an interconnection layer electrically connected to the electrode film via the foundation metal film and the bonding metal portions.

8. The member according to claim 7, further comprising:
an insulating film provided between the side surface of the second through hole and the electrode film.

9. The member according to claim 7, further comprising:
a second foundation metal film provided between a face of the second substrate facing the first substrate and the bonding metal portions, and electrically connected to the electrode film.

10. The member according to claim 9, further comprising:
an insulating film provided between the face of the second substrate facing the first substrate and the second foundation metal film.

11. The member according to claim 1, wherein
the bonding metal portions mainly contain gold,
the foundation metal film mainly includes palladium, titanium, or a stacked film of a palladium film and a titanium film, and
the conductive film mainly contains titanium nitride.
